(19) United States
(12) Patent Application Publication
(10) Pub. No.: US 2020/0313648 A1
(43) Pub. Date: Oct. 1, 2020

(54) Single-Crystal Bulk Acoustic Wave Resonator and Method of Making Thereof

(71) Applicant: Global Communication Semiconductors, LLC, Torrance, CA (US)

(72) Inventors: Shing-Kuo Wang, Torrance, CA (US); Liping Daniel Hou, Torrance, CA (US)

(21) Appl. No.: 16/368,754

(22) Filed: Mar. 28, 2019

(51) Int. Cl. H03H 9/17; H03H 9/02; H03H 9/10; H03H 9/54

(52) U.S. Cl. CPC H03H 9/17; H03H 9/02015; H03H 9/54; H03H 9/1042; H03H 9/02047

(57) ABSTRACT

Design and processes are described for fabricating single-crystal bulk acoustic wave resonators with better performance and better manufacturability. A low-acoustic-loss single-crystal piezoelectric layer is epitaxially grown on a substrate, followed with the formation of bottom electrode, metallic cavity frames, and gap filler material on the piezoelectric layer. Matching metallic cavity frames and gap filler material are formed on a second substrate. The two wafers are then bonded together by metal-to-metal bonding of the metallic cavity frames on the first wafer to the matching metallic cavity frame on the second wafer to form a sealed cavity between the bottom electrodes and the second wafer. The first substrate is then removed to expose the piezoelectric layer. This second wafer and the structures thereon are then ready to complete the BAW resonator and filter fabrication using standard wafer processing steps.

### TECHNICAL FIELD

The disclosed embodiments relate generally to bulk acoustic wave resonators, and in particular, to single-crystal film bulk acoustic wave resonators and method of making thereof.

### BACKGROUND

A bulk acoustic wave (BAW) resonator (or BAWR) typically includes a piezoelectric thin film layer between a bottom electrode and a top electrode. When an oscillating electrical signal is applied between the top and bottom electrodes, the piezoelectric thin film layer converts the oscillating electrical signal into bulk acoustic waves. The resonance frequency of the BAW resonator is mainly determined by the acoustic velocity and thickness of the piezoelectric layer and the electrodes. Piezoelectric thin film materials used for bulk acoustic wave devices include AlN, ZnO thin films for small bandwidth applications and PZT films for wide bandwidth applications. BAW resonators are widely used in RF filters in mobile devices due to their compact size and high performance.

The performance of BAW resonators is primarily determined by the acoustic property of the piezoelectric thin films, characterized by their electromechanical coupling coefficients (K²_{eff}) and Q-factor. Piezoelectric thin films showing high electromechanical coupling coefficient (e.g., K²_{eff}˜10%) can be used for wide bandwidth filter applications. Currently, BAW resonators are normally constructed by depositing piezoelectric (e.g., AlN) thin films via physical vapor deposition (PVD) techniques such as sputter deposition. The resulting PVD AlN thin films are poly-crystalline, which have significantly lower crystalline quality and thus lower electromechanical coupling coefficient compared to single crystal AlN films. Furthermore, it has been reported (e.g., in S. R. Choi, “Thermal Conductivity of AlN and SiC Thin Films” Int. Jo. of Thermophysics, p 896, 2006) that thermal conductivity of polycrystalline AlN thin films degrades as film thickness decreases, resulting in compromised power handling capability of the associated BAW resonators.

### SUMMARY

Accordingly, there is a need for a BAW resonator with an electromechanical coupling coefficient higher than what can be achieved by conventional fabrication methods. There is also a need for a method for fabricating such a BAW resonator that is cost-effective and applicable in a mass production environment.

In some embodiments, a bulk acoustic resonator includes a substrate, a cavity frame over the substrate, the cavity frame including first and second metal frames bonded together by metal-to-metal bonding, a first electrode over the cavity frame, wherein the first electrode, the cavity frame and the substrate together define a cavity under the first electrode; a piezoelectric layer over the first electrode, the piezoelectric layer including an epitaxially grown crystalline material; and a second electrode over the piezoelectric layer. The first electrode coupled to a first side of a piezoelectric layer and the second electrode coupled to a second side of the piezoelectric layer is referred to as a BAW stack or stack. The stack is configured to resonate in response to an electrical signal applied between the first electrode and the second electrode.

In some embodiments, a process of fabricating a bulk acoustic resonator comprises epitaxially growing a piezoelectric film on a first substrate, depositing and then patterning a film of electrically conductive material to form a first electrode on a first side of the piezoelectric film, and forming a first metal frame on the first electrode. The process further comprises forming a second metal frame on a second substrate, the second metal frame at least partially matching the first metal frame, and bonding the first metal frame to the second metal frame via metal-to-metal bounding to form a cavity between the first electrode and the second substrate. The process further comprises removing the first substrate to expose a second side of the piezoelectric film, the second side being opposite to the first side, forming a second electrode on the second side of the piezoelectric film, and forming metal contacts and interconnect metal lines for the BAW resonator.

Thus, the process of fabricating a bulk acoustic resonator according to some embodiments allows the bulk acoustic resonator to have an epitaxially grown piezoelectric thin film layer, and forms the resonator cavity without requiring additional sacrificial layer deposition and removal. The process is cost-effective and applicable in a mass production environment because it does not require complicated backside processing. The BAW resonator thus formed is characterized by good confinement of the bulk acoustic wave energy, a high degree of crystallinity, and minimal dispersion loss of acoustic signals.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

FIG. 1A is a cross-sectional diagram of a bulk acoustic wave resonator, in accordance with some embodiments.

FIG. 1B is a top-down view of a bulk acoustic wave resonator, in accordance with some embodiments.

FIGS. 2A-2L are cross-sectional diagrams illustrating a process of fabricating a bulk acoustic wave resonator, in accordance with some embodiments.

FIG. 3 illustrates a flowchart representation of a process for fabricating a bulk acoustic wave resonator, in accordance with some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

The various embodiments described herein include systems, methods and/or devices with structures for improved performance and manufacturability

(A1) More specifically, some embodiments include a bulk acoustic resonator that includes a substrate, a cavity frame over the substrate, a first electrode over the cavity frame, a piezoelectric layer over the first electrode, and a second electrode over the piezoelectric layer. The cavity frame includes first and second metal frames bonded together by metal-to-metal bonding. The first electrode, the cavity frame and the substrate together define a cavity under the first electrode. The piezoelectric layer includes an epitaxially grown crystalline material.

(A2) In some embodiments of the bulk acoustic resonator of A1, the cavity frame is physically in contact with the substrate on one side and with the first electrode on the other side, distal the first side.

(A3) In some embodiments of the bulk acoustic resonator of any of A1 and A2, the second metal frame is formed on the substrate, and wherein the first metal frame, the first electrode, and the piezoelectric layer are transferred from another substrate that is subsequently removed, the first metal frame having a pattern at least partially matching that of the second metal frame.

(A4) In some embodiments of the bulk acoustic resonator of any of A1-A3, the first electrode is formed on a first side of the piezoelectric layer, and the second electrode is formed on a second side of the piezoelectric layer opposite to the first side of the piezoelectric layer after the other substrate is removed.

(A5) In some embodiments of the bulk acoustic resonator of any of A1-A4, the first electrode is physically in contact with the first side of the piezoelectric layer, and the second electrode is physically in contact with the second side of the piezoelectric layer.

(A6) In some embodiments of the bulk acoustic resonator of any of A1-A5, the first metal frame is formed on the first electrode and the second metal frame is formed on the substrate.

(A7) In some embodiments of the bulk acoustic resonator of any of A1-A6, the first metal frame and the second metal frame are each a single layer, or multiple layers, or alloyed, as long as they can be bonded together. Typically, their sizes (widths) are different to tolerate misalignment.

(A8) In some embodiments of the bulk acoustic resonator of A1-A7, further comprises a filler outside the cavity and surrounding the cavity frame, the filler including a first filler layer and a second filler layer, wherein the first filler layer is over the second filler layer and at least partially aligned with the second filler layer.

(A9) In some embodiments of the bulk acoustic resonator of A8, the second filler layer is formed on the substrate, and the first filler layer is transferred from another substrate.

(A10) In some embodiments of the bulk acoustic resonator of any of A1-A9, the second filler layer is physically in contact with the substrate, and the first filler layer is physically in contact with the piezoelectric layer and the first electrode.

(A11) In some embodiments of the bulk acoustic resonator of any of A1-A10, the piezoelectric layer is epitaxially grown on another substrate that is subsequently removed.

(A12) In some embodiments of the bulk acoustic resonator of any of A1-A11, the first and second electrodes include Molybdenum (Mo), Tungsten (W) or Ruthenium (Ru).

(A13) In some embodiments of the bulk acoustic resonator of any of A1-A12, the piezoelectric layer includes aluminum nitride (AlN), scandium aluminum nitride (SLAIN), Zinc Oxide (ZnO), or lead zirconate titanate (PZT).

(A14) In some embodiments of the bulk acoustic resonator of A13, the cavity frame includes gold (Au), or a gold-alloy, such as gold-tin (AuSn), or gold-indium (AuIn).

(A18) Some embodiments include a bulk acoustic resonator prepared by a process comprising the steps of: epitaxially growing a layer of piezoelectric material on a first substrate, forming a first electrode layer on a first side of the layer of piezoelectric material, forming a first metal frame over the first electrode layer, forming a second metal frame over a second substrate, the second metal frame at least partially matching the first metal frame, bonding the first metal frame with the second metal frame to form a cavity frame, removing the first substrate to exposed a second side of the layer of piezoelectric material, and forming a second electrode layer on the second side of the layer of piezoelectric material.

(A19) In some embodiments of the bulk acoustic resonator of claim A18, the first metal frame is bonded with the second metal frame by metal-to-metal bonding.

(A20) In some embodiments of the bulk acoustic resonator of A18-A19, the first metal frame is formed over the first electrode layer using physical deposition, or electroplating.

(A21) In some embodiments of the bulk acoustic resonator of A20, the second metal frame is formed over the second substrate using physical deposition, or electroplating.

(A22) In some embodiments of the bulk acoustic resonator of any of A18-A21, the process includes forming a first filler layer on the first substrate, the first filler layer surrounding the first metal frame.

(A23) In some embodiments of the bulk acoustic resonator of A22, the process includes forming a second filler layer on the second substrate, the second filler layer surrounding the second metal frame and having a pattern at least partially matching that of the first filler layer.

(A24) In some embodiments of the bulk acoustic resonator of any of A18-A23, removing the first substrate comprises polishing or grinding a back side of the first substrate to remove a main portion of the first substrate and removing a remaining portion of the first substrate using a selective etching process to expose the second side of the layer of piezoelectric material.

(A25) In some embodiments of the bulk acoustic resonator of any of A18-A24, the first and second electrode layers include Molybdenum (Mo), Tungsten (W) or Ruthenium (Ru).

(A26) In some embodiments of the bulk acoustic resonator of A25, the layer of piezoelectric material includes single crystal aluminum nitride (AlN), scandium aluminum nitride (ScAlN), Zinc Oxide (ZnO), or lead zirconate titanate (PZT).

(A27) In some embodiments of the bulk acoustic resonator of A26, the cavity frame includes gold (Au), or a gold alloy, such as gold-tin (AuSn), or gold-indium (AuIn).

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

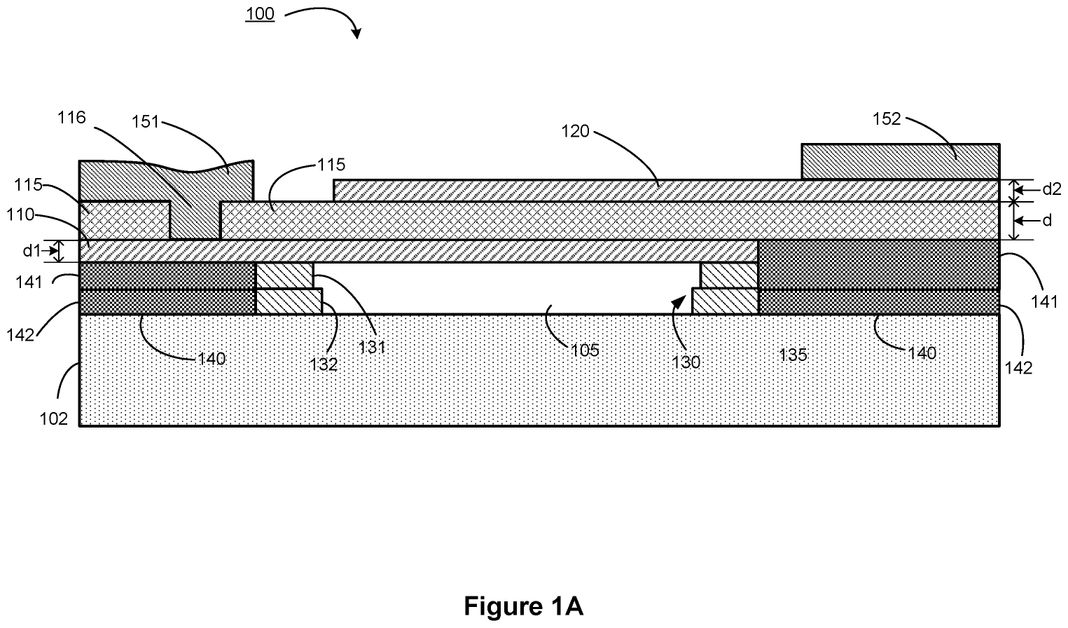

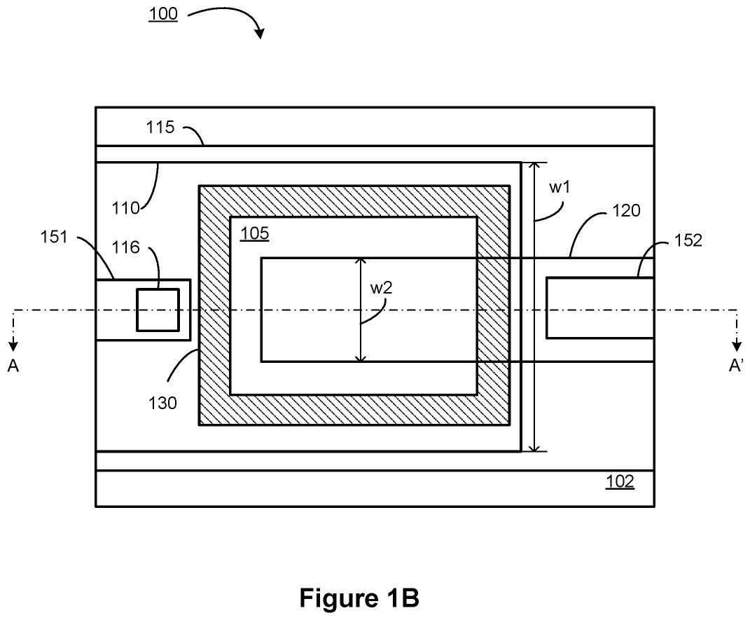

FIG. 1A is a cross-sectional diagram of a bulk acoustic wave (BAW) resonator 100, in accordance with some embodiments. Bulk acoustic resonator 100 includes a substrate 102, a cavity frame 130 over the substrate 102, a first electrode 110 over the cavity frame 130, a piezoelectric layer 115 over the first electrode 110, and a second electrode 120 over the piezoelectric layer 115. In some embodiments, the cavity frame 130 includes a first metal frame 131 and a second metal frame 132 bonded together by metal-to-metal bonding 135. The first metal frame 131 and the second metal frame 132 each can be a single layer, or multiple layers, of one or more metals or metal alloys. In some embodiments, the first metal frame 131 and the second metal frame 132 have respective patterns that match each other although the respective patterns can be slightly different to tolerate misalignment. For example, as shown in FIG. 1A, metal layer 132 has a wider dimension in at least one direction than metal layer 131 to allow misalignment during a bonding process. In some embodiments, bulk acoustic resonator 100 includes a filler 140 outside the cavity 105 and surrounding the cavity frame 130. The filler 140 includes a first filler layer 141 and a second filler layer 142 under and at least partially aligned with the first filler layer 141. In some embodiments, the first filler layer 141 is physically in contact with part of the piezoelectric layer 115 and with the first electrode 110 and the second filler layer 141 is physically in contact with the substrate 102. The first electrode 110, the cavity frame 130, and the substrate 102 together define a cavity 105 under and/or adjacent to the first electrode 110. In some embodiments, the piezoelectric layer 115 includes an epitaxially grown crystalline material. In some embodiments, the piezoelectric layer 115 includes an epitaxially grown single crystal material. In some embodiments, the cavity frame 130 is physically in contact with the substrate 102 on one side and the first electrode 110 on the other side, distal the first side.

The first electrode 110, the piezoelectric layer 115, and the second electrode 120 form a BAW stack configured to resonate in response to an electrical signal applied between the first electrode 110 and the second electrode 120. Cavity 105 provides a space between the substrate 102 and the first electrode 110 in which the BAW stack is free to resonate in response to electrical signals provided between first electrode 110 and second electrode 120 so as to reduce acoustic energy leak into the substrate 102. In some embodiments, the bulk acoustic resonator 100 includes a first contact 151 formed at least partially within a contact hole 116 to create an electrical contact with first electrode 110 and a second contact 152 at least partially in contact with second electrode 120. The first contact 151 and the second contact 152 provide electrical contacts with the first electrode 110 and the second electrode 120, respectively, to allow an electrical signal to be applied between the first electrode 110 and the second electrode 120. In some embodiments, the first electrode 110 is physically in contact with the first side of the piezoelectric layer 115, and the second electrode 120 is physically in contact with the second side of the piezoelectric layer 115, opposite to the first side.

FIG. 1B is a top-down view of bulk acoustic resonator 100 illustrating lateral arrangement of various layers, including a substrate 102, cavity frame 130 around cavity 105, first electrode 110 over the cavity frame 130, piezoelectric layer 115 over the first electrode 110, second electrode 120 over the piezoelectric layer 115, contact hole 116, first contact 151, and second contact 152.

In some embodiments, piezoelectric layer 115 has a thickness d of about 100 nanometers to 2 micrometers, and each of the first and second electrode 110 or 120 has a thickness d1 or d2, respectively, of about 20 nanometers to about 500 nanometers. In some embodiments, each of the first and second electrodes 110 or 120 has a width w1 or w2, respectively, of about 20-200 micrometers. In some embodiments, substrate 102 includes silicon, glass, ceramic, gallium arsenide and/or silicon carbide, the first second electrode 110 and the second electrode 120 each includes Molybdenum (Mo), Tungsten (W), and/or Ruthenium (Ru), and the piezoelectric layer includes an epitaxially grown layer of piezoelectric material, such as aluminum nitride (AlN), scandium aluminum nitride (ScAlN), Zinc Oxide (ZnO), or lead zirconate titanate (PZT), etc. In some implementations, the cavity frame 130 includes metal or metal alloy, such as gold (Au), gold-tin (AuSn), or gold-indium (AuIn).

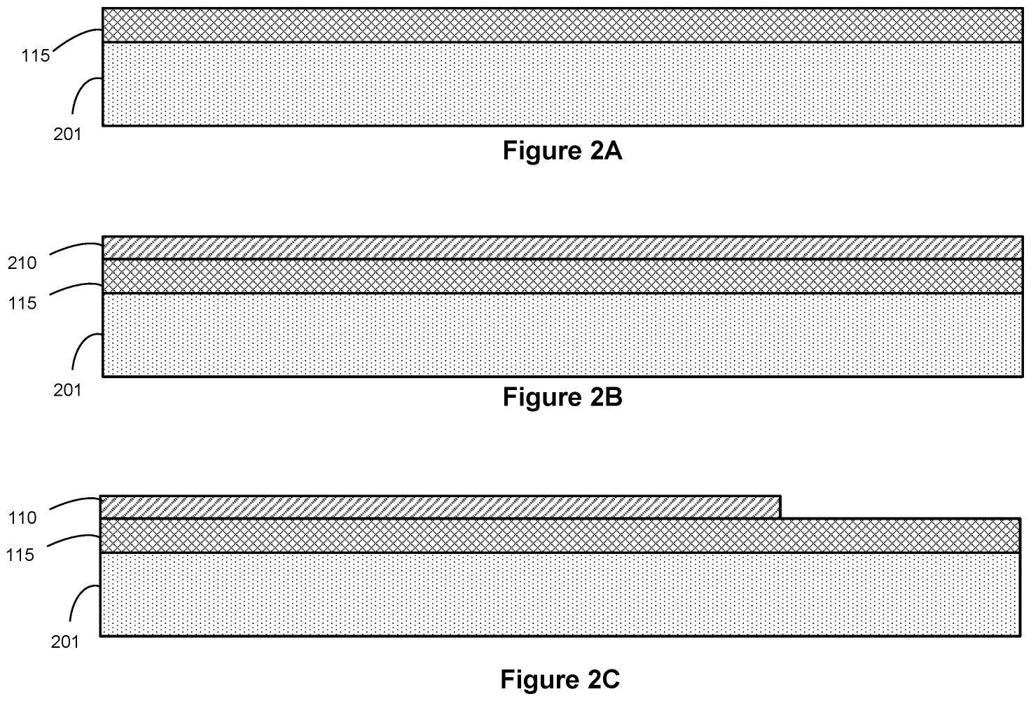

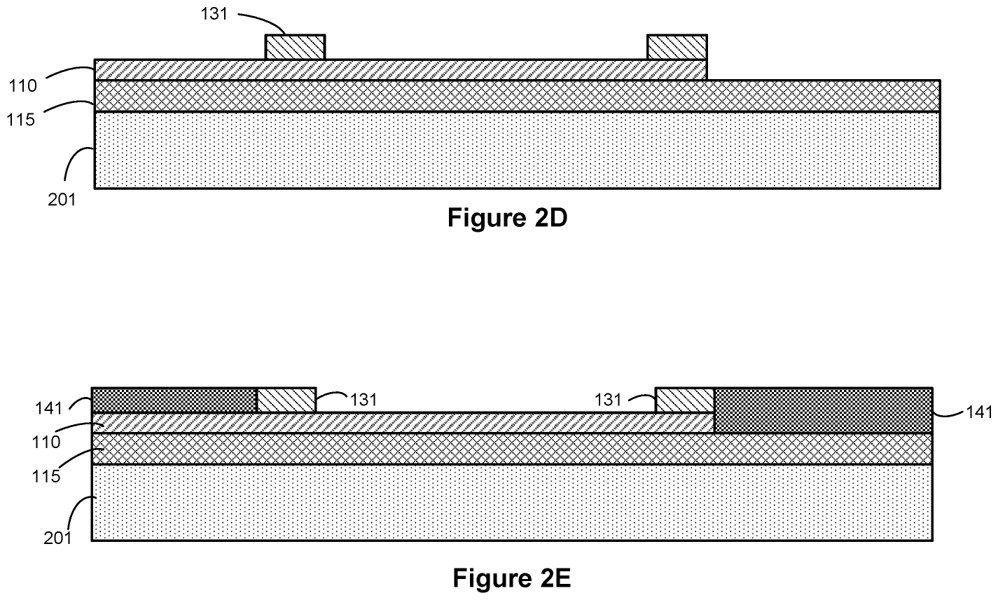

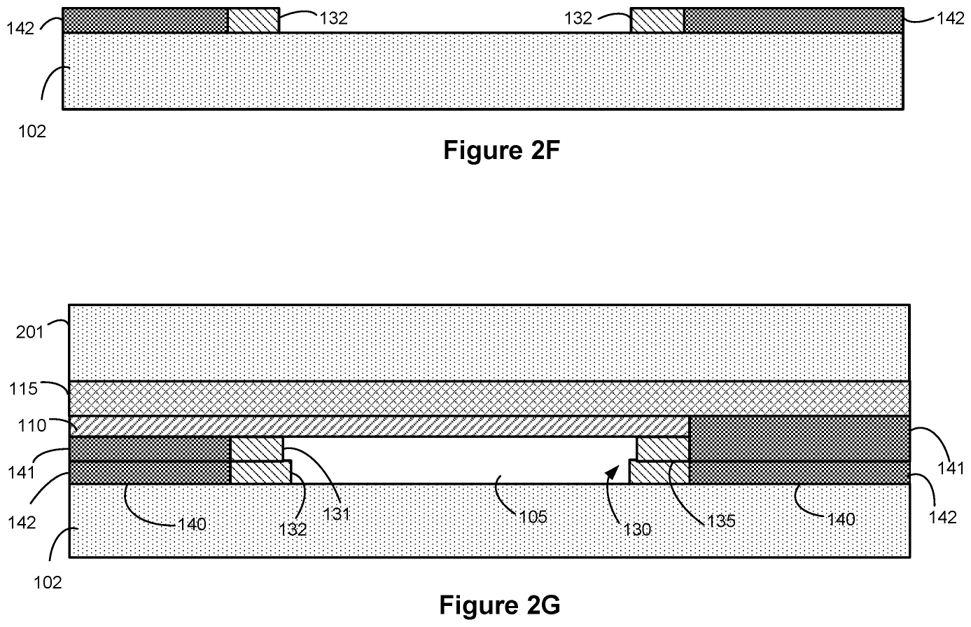

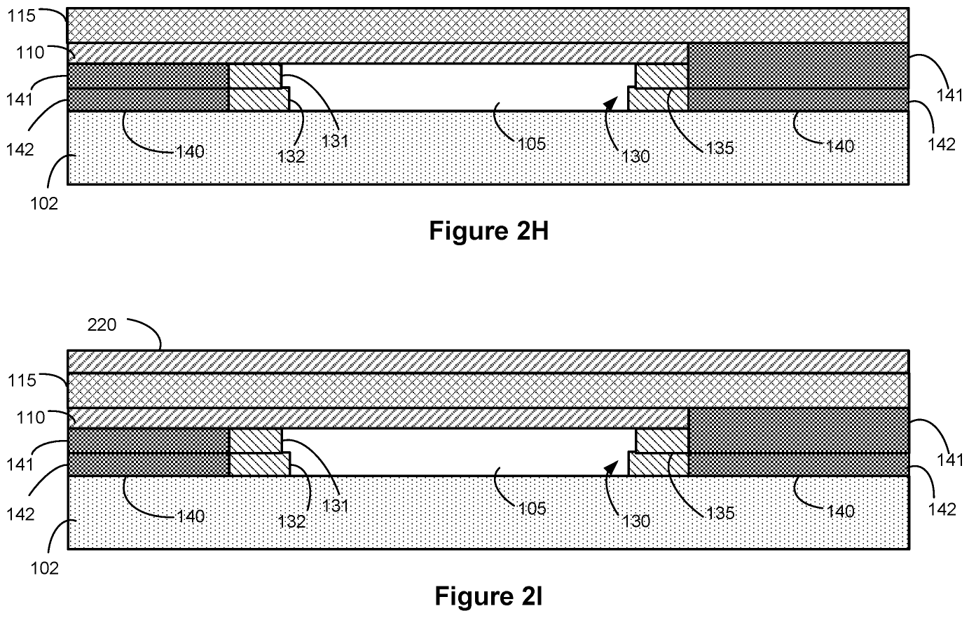

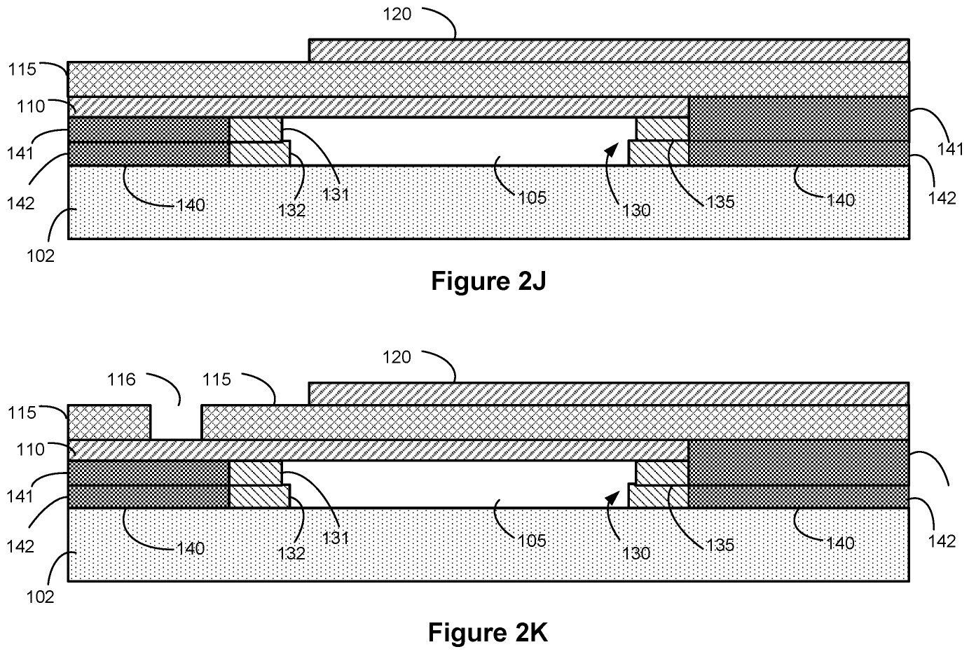

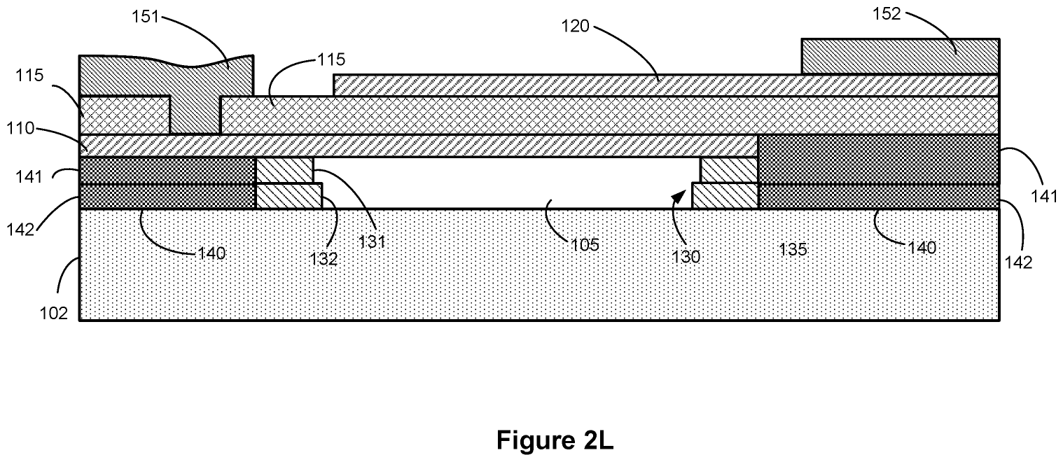

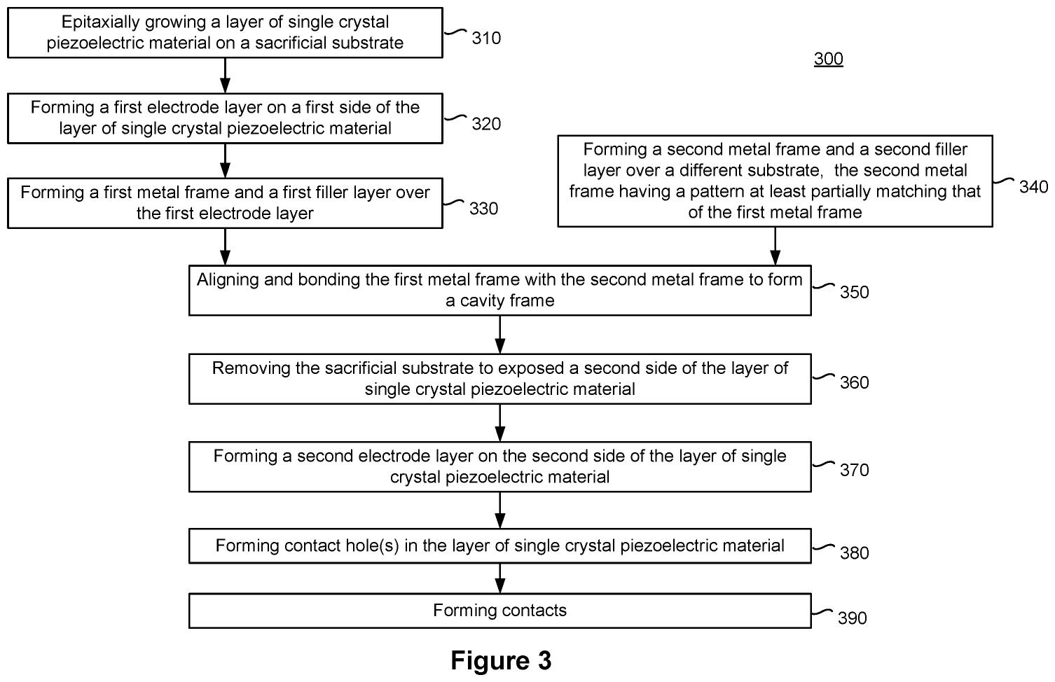

FIGS. 2A-2L and FIG. 3 illustrate a process 300 for fabricating the bulk acoustic resonator 100, in accordance with some embodiments. FIGS. 2A-2L illustrate cross-sectional views of bulk acoustic resonator 100 at various stages of process 300, in accordance with some embodiments. FIG. 3 is a flowchart representation of process 300, in accordance with some embodiments.

As shown in FIG. 2A and FIG. 3, at step 310 of process 300, a layer of crystalline piezoelectric material 115 (e.g., aluminum nitride, scadium-aluminum nitride, and/or zinc oxide) is epitaxially grown on a sacrificial substrate 201 (e.g., single crystal silicon, sapphire, gallium arsenide and/or silicon carbide). For example, a crystalline (e.g., single crystal) AlN piezoelectric layer 115 can be epitaxially grown on a single crystal silicon (Si) (111) or Si (100) substrate using, for example, chemical vapor deposition, plasma-assisted molecular beam epitaxy, pulsed laser deposition, metalorganic chemical vapor deposition (MO-CVD), hydride vapor phase epitaxy (HVPE), ultra-high vacuum (UHV) reactive dc-magnetron sputtering, etc.

As shown in FIGS. 2B and 2C, and FIG. 3, at step 320 of process 300, a first electrode layer 210 (e.g., molybdenum, aluminum, and/or tungsten) is formed on a first side of the layer of piezoelectric material 115 using, for example, sputter deposition, and is subsequently patterned to form first electrode 110 using plasma etching or wet chemical etching.

As shown in FIG. 2D, and FIG. 3, at step 330 of process 300, a first metal frame 131 is formed over the first electrode 110 using one or more processes, such as, for example, evaporation deposition combined with lift-off patterning or selective electroplating.

In FIG. 2E first filler layer 141 is formed on the sacrificial substrate 201 (e.g., filling the exterior or outer spaces on the first substrate 201 created by the formed first metal frame 131 over the first electrode 110.) In some embodiments, first filler layer 141 includes a polymer material such as polyimide, and first filler layer 141 is formed using spin coating or fluid ejection, which may be followed by, for example, photolithography.

As shown in FIG. 2F, and FIG. 3, at step 340 of process 300, second metal frame 132 is formed over substrate 102 using one or more processes, such as, for example, evaporation deposition and lift-off patterning or selective electroplating. A second filler layer 142 is formed on substrate 102 (e.g., filling the exterior or outer spaces on the second substrate 102 created by the formed second metal frame 132 over the second substrate 102.) In some embodiments, second filler layer 142 includes a polymer material such as polyimide, and second filler layer 142 is formed using spin coating or fluid ejection, which may be followed by, for example, photolithography

As shown in FIG. 2G, and FIG. 3, at step 350 of process 300, the first metal frame 131 is aligned and bonded with the second metal frame 132 to form a cavity frame 130. In some embodiments, the first metal frame 131 and the second metal frame 132 are bonded using a solid phase metal-to-metal bonding process to form a metal-to-metal bond 135 between the first metal frame 131 and the second metal frame 132. The first electrode 110, the cavity frame 130, and the second substrate 102 together define a cavity 105 under the first electrode 110.

As shown in FIG. 2H, and FIG. 3, at step 360 of process 300, the sacrificial substrate 201 is removed using one or more processes, such as chemical mechanical polishing or grinding followed by plasma etching or wet chemical etching, to expose a second side of the layer of piezoelectric material 115. Other methods instead of, or in addition to, chemical mechanical polishing or grinding, and plasma etching or wet chemical etching, may also be used at step 360 to mechanically remove the sacrificial substrate 201 from the piezoelectric layer 115.

As shown in FIGS. 2I-2J, and FIG. 3, at step 370 of process 300, a second electrode 120 (e.g., molybdenum, aluminum, and/or tungsten) is formed on the second side of the layer of piezoelectric material 115. As shown in FIG. 2I, forming the second electrode 120 includes depositing a second electrode layer 220 (e.g., molybdenum, aluminum, and/or tungsten) on the second side of the layer of piezoelectric material 115 using, for example, sputter deposition.

As shown in FIG. 2J, and FIG. 3, at step 370 of process 300, forming the second electrode 120 further includes patterning the second electrode layer 220, using, for example, plasma etching or wet chemical etching.

In FIG. 2K and FIG. 3, at step 380 of process 300, contact hole 116 is etched in piezoelectric layer 115 using plasma etching to provide access to first electrode 110 via a subsequently formed first contact 151.

In FIG. 2L and FIG. 3, at step 390 of process 300, first contact 151 and a second contact 152 are formed using conventional processes, such as evaporation deposition, lift-off patterning, or selective electroplating.

It will be understood that, although the terms “first,” “second,” etc. may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A bulk acoustic resonator, comprising:
a substrate;
a cavity frame over the substrate, the cavity frame including first and second metal frames bonded together by metal-to-metal bonding;
a first electrode over the cavity frame, wherein the first electrode, the cavity frame and the substrate together define a cavity under the first electrode;
a piezoelectric layer over the first electrode, the piezoelectric layer including an epitaxially grown crystalline material; and
a second electrode over the piezoelectric layer.

2. The bulk acoustic resonator of claim 1, wherein the first metal frame is formed on the substrate, wherein the second metal frame, the first electrode and the piezoelectric layer are transferred from another substrate that is subsequently removed, the second metal frame having a pattern at least partially matching that of the first metal frame.

3. The bulk acoustic resonator of claim 2, wherein the first electrode is formed on a first side of the piezoelectric layer, and the second electrode is formed on a second side of the piezoelectric layer opposite to the first side of the piezoelectric layer after the other substrate is removed.

4. The bulk acoustic resonator of claim 1, wherein the first metal frame is formed on the first electrode and the second metal frame is formed on the substrate.

5. The bulk acoustic resonator of claim 1, further comprising a filler outside the cavity and surrounding the cavity frame, the filler including a first filler layer and a second filler layer, wherein the first filler layer is over the second filler layer and at least partially aligned with the second filler layer.

6. The bulk acoustic resonator of claim 5, wherein the second filler layer is formed on the substrate, and the first filler layer is transferred from another substrate.

7. The bulk acoustic resonator of claim 1, wherein the piezoelectric layer is epitaxially grown on another substrate that is subsequently removed.

8. The bulk acoustic resonator of claim 1, wherein the first and second electrodes include Molybdenum (Mo), Tungsten (W) or Ruthenium (Ru).

9. The bulk acoustic resonator of claim 8, wherein the piezoelectric layer includes aluminum nitride (AlN), scandium aluminum nitride (SLAIN), Zinc Oxide (ZnO), or lead zirconate titanate (PZT).

10. The bulk acoustic resonator of claim 9, wherein the cavity frame includes gold (Au) or a gold alloy.

11. A method of fabricating a bulk acoustic resonator, comprising:
epitaxially growing a piezoelectric material on a first substrate;
forming a first electrode layer on a first side of the piezoelectric material;
forming a first metal frame over the first electrode layer;
forming a second metal frame over a second substrate, the second metal frame at least partially matching the first metal frame;
bonding the first metal frame with the second metal frame to form a cavity frame;
removing the first substrate to exposed a second side of the piezoelectric material; and
forming a second electrode layer on the second side of the layer of piezoelectric material.

12. The method of claim 11, wherein the first metal frame is bonded with the second metal frame by metal-to-metal bonding.

13. The method of claim 11, wherein the first metal frame is formed over the first electrode layer using physical deposition or electroplating.

14. The method of claim 13, wherein the second metal frame is formed over the second substrate using physical deposition or electroplating.

15. The method of claim 11, further comprising forming a first filler layer on the first substrate.

16. The method of claim 15, further comprising, forming a second filler layer on the second substrate, the second filler layer having a pattern at least partially matching that of the first filler layer.

17. The method of claim 11, wherein removing the first substrate comprises grinding or polishing a back side of the first substrate to remove a main portion of the first substrate and removing a remaining portion of the first substrate using plasma or chemical etching to expose the second side of the layer of piezoelectric material.

18. The method of claim 11, wherein the first and second electrode layers include Molybdenum (Mo), Tungsten (W) or Ruthenium (Ru).

19. The method of claim 18, wherein the layer of piezoelectric material includes single crystal aluminum nitride (AlN), scandium aluminum nitride (ScAlN), Zinc Oxide (ZnO), or lead zirconate titanate (PZT).

20. The method of claim 19, wherein the cavity frame includes gold (Au) or a gold alloy.
